(19) United States
(12) Patent Application Publication
(10) Pub. No.: US 2015/0008544 A1
(43) Pub. Date: Jan. 8, 2015

(54) PHYSICAL QUANTITY SENSOR

(71) Applicant: ALPS ELECTRIC CO., LTD., Tokyo (JP)

(72) Inventors: Hisayuki YAZAWA, Tokyo (JP); Katsuya KIKUIRI, Tokyo (JP); Toru TAKAHASHI, Tokyo (JP)

(21) Appl. No.: 14/321,947

(22) Filed: Jul. 2, 2014

(30) Foreign Application Priority Data
Jul. 2, 2013 (JP) 2013-138931

(51) Int. Cl. B81B 7/00; G01L 9/00

(52) U.S. Cl. CPC B81B 7/0064; G01L 9/0054
USPC 257/417

(57) ABSTRACT

A physical quantity sensor detects a physical quantity using a piezoresistive effect and includes a first-conductivity-type well layer disposed on a first insulating layer, a plurality of second-conductivity-type piezoresistive layers disposed on a surface side of the first-conductivity-type well layer, and a second-conductivity-type isolation layer disposed between the plurality of second-conductivity-type piezoresistive layers so as to pass through the first-conductivity-type well layer from a surface of the first-conductivity-type well layer to a surface of the first insulating layer.

### CLAIM OF PRIORITY

This application claims benefit of Japanese Patent Application No. 2013-138931 filed on Jul. 2, 2013, which is hereby incorporated by reference.

### BACKGROUND OF THE INVENTION

1. Field of the Invention

The present invention relates to a physical quantity sensor which detects a physical quantity using a piezoresistive effect.

2. Description of the Related Art

In the related art, physical quantity sensors which detect a physical quantity, such as pressure, acceleration, or load, using the piezoresistive effect of a semiconductor, such as silicon, are known. For example, as a physical quantity sensor which detects automobile tire pressure or the like, a diaphragm-type pressure sensor is known.

FIG. 12 is a cross-sectional view of a pressure sensor disclosed in Japanese Patent No. 2789291 (Patent Document 1). FIG. 13 is a cross-sectional view of a diaphragm of the pressure sensor disclosed in Patent Document 1. A pressure sensor 220 according to a related art example disclosed in Patent Document 1 includes, as shown in FIG. 12, a P-type semiconductor silicon substrate 231 provided with a fixed portion (thick portion) 222 and a thin diaphragm 221.

In the diaphragm 221, as shown in FIG. 13, a plurality of well layers 204a and 204b, which are N⁺-type impurity layers, are disposed in the P-type semiconductor silicon substrate 231. Piezoresistive layers 202a and 202b, which are P⁺-type impurity layers, each having a piezoresistive effect, are respectively disposed within the well layers 204a and 204b, which are N⁺-type impurity layers.

When a plurality of well layers 204a and 204b and the silicon substrate 231, which is itself an impurity layer, are reverse-biased, the well layers 204a and 204b are insulated and isolated from one another. Furthermore, since a plurality of piezoresistive layers 202a and 202b are respectively provided within the well layers 204a and 204b which are insulated and isolated from one another, the piezoresistive layers 202a and 202b are insulated and isolated from one another. In such a manner, in the pressure sensor 220 according to the related art example, after a plurality of well layers 204a and 204b are formed in the silicon substrate 231, the piezoresistive layers 201a and 202b are formed within the well layers 204a and 204b.

An insulating layer 211 composed of a silicon oxide film or the like is disposed on the surface of the silicon substrate 231, and an interconnection layer 208 composed of aluminum (Al) or the like having a predetermined pattern is disposed on the insulating layer 211. First connection holes 213a and second connection holes 213b which pass through the insulating layer 211 are provided, and the interconnection layer 208 is connected to the piezoresistive layers 202a and 202b and the well layers 204a and 204b to constitute a bridge circuit.

In the pressure sensor 220 according to the related art example, as shown in FIG. 13, a plurality of well layers 204a and 204b and a plurality of piezoresistive layers 202a and 202b disposed in the silicon substrate 231 are impurity layers. The impurity layers are formed by doping the silicon substrate 231 with an impurity element, such as boron (B) or phosphorus (P), by ion implantation or the like.

Since the impurity layers are formed by doping the silicon substrate 231 with an impurity element, deformation is likely to occur in the impurity layers. Because of the deformation, crystal defects, such as lattice defects and dislocations, are likely to occur in the impurity layers.

After ion implantation is performed, annealing treatment is performed in order to activate the impurity element and restore crystal defects or the like. Crystal defects are reduced by annealing treatment. However, in the pressure sensor 220 according to the related art example, the silicon substrate 231 is doubly doped with the impurity element for forming the piezoresistive layers 202a and 202b and the impurity element for forming the well layers 204a and 204b. Accordingly, in the pressure sensor 220 according to the related art example, the amount of deformation in the piezoresistive layers 202a and 202b and the amount of deformation in the periphery thereof are large, and annealing treatment cannot sufficiently reduce crystal defects in the piezoresistive layers 202a and 202b and crystal defects in the periphery thereof.

Consequently, in the pressure sensor 220 according to the related art example, crystal defects may be present in the junction planes between the piezoresistive layers 202a and 202b and the well layers 204a and 204b and the junction planes between the well layers 204a and 204b and the silicon substrate 231, which is itself an impurity layer, and leakage currents may occur at the junction planes in some cases.

When leakage currents occur at the junction planes between the piezoresistive layers 202a and 202b and the well layers 204a and 204b, currents flowing in the piezoresistive layers 202a and 202b vary in response to the leakage currents. Therefore, in the pressure sensor 220 according to the related art example, pressure detection accuracy is degraded, which is a problem.

When leakage currents occur at the junction planes between the well layers 204a and 204b and the silicon substrate 231, which is itself an impurity layer, potentials of the well layers 204a and 204b vary, and thus, the value of voltage that reverse-biases the piezoresistive layers 202a and 202b and the well layers 204a and 204b varies. Therefore, dark currents flowing between the piezoresistive layers 202a and 202b and the well layers 204a and 204b may vary, and currents flowing in the piezoresistive layers 202a and 202b may vary in some cases. Therefore, in the pressure sensor 220 according to the related art example, pressure detection accuracy is degraded, which is a problem.

In the pressure sensor 220 according to the related art example, as shown in FIG. 13, when a plurality of well layers 204a and 204b and the silicon substrate 231, which is itself an impurity layer, are reverse-biased, the well layers 204a and 204b are insulated and isolated from one another. In such a manner, in the pressure sensor 220 according to the related art example, since insulation/isolation is provided using only junction planes between reverse-biased semiconductor impurity layers, insulation/isolation between a plurality of well layers 204a and 204b is insufficient. Therefore, in the pressure sensor 220 according to the related art example, pressure detection accuracy is degraded, which is a problem.

### SUMMARY OF THE INVENTION

The present invention provides a physical quantity sensor which detects a physical quantity using a piezoresistive effect and which has excellent detection accuracy.

A physical quantity sensor according to the present invention detects a physical quantity using a piezoresistive effect and includes a first-conductivity-type well layer disposed on a first insulating layer, a plurality of second-conductivity-type piezoresistive layers disposed on a surface side of the first-conductivity-type well layer, and a second-conductivity-type isolation layer disposed between the plurality of second-conductivity-type piezoresistive layers so as to pass through the first-conductivity-type well layer from a surface of the first-conductivity-type well layer to a surface of the first insulating layer.

In such a configuration, a plurality of piezoresistive layers and the well layer located in the periphery of the plurality of piezoresistive layers are not doubly doped with impurity elements. Accordingly, in the physical quantity sensor of the present invention, the amounts of deformation in the plurality of piezoresistive layers and in the periphery of the plurality of piezoresistive layers are small, and therefore, crystal defects in the plurality of piezoresistive layers and in the periphery of the plurality of piezoresistive layers can be sufficiently reduced.

Since each well layer is insulated and isolated using the first insulating layer, it is possible to reduce the junction planes between the well layers and the isolation layer to be reverse-biased. Therefore, in the insulation/isolation of the well layers according to the present invention, insulating performance is high compared with the case where insulation/isolation is provided using only junction planes between reverse-biased semiconductor impurity layers.

Consequently, according to the present invention, it is possible to provide a physical quantity sensor which detects a physical quantity using a piezoresistive effect and which has excellent detection accuracy.

Preferably, the plurality of second-conductivity-type piezoresistive layers include a first piezoresistive layer disposed at a position close to a power source pad and a second piezoresistive layer disposed at a position far from the power source pad, a bridge circuit is constituted by a first piezoresistive element including the first piezoresistive layer and a second piezoresistive element including the second piezoresistive layer, and the isolation layer is disposed between the first piezoresistive element and the second piezoresistive element.

The change in resistance of each piezoresistive element varies with the distance from the power source. Piezoresistive elements located at different distances from a power source have different potentials and different resistance changes due to dark currents caused by reverse biasing. Accordingly, by isolating the piezoresistive element close to the power source pad from the piezoresistive element far from the power source by the isolation layer, the potential of each piezoresistive element can be independently adjusted by an adjustment circuit. Thereby, the resistance change due to dark currents can be adjusted to be the same for the piezoresistive element close to the power source and the piezoresistive element far from the power source. Thus, it is possible to achieve a physical quantity sensor having excellent detection accuracy.

Preferably, the second-conductivity-type isolation layer is disposed so as to surround the first-conductivity-type well layer. In such a configuration, each well layer on which a plurality of piezoresistive layers are disposed can be insulated and isolated without being restricted by the layout of the plurality of piezoresistive layer.

Preferably, each of first-conductivity-type well layers on which the plurality of second-conductivity-type piezoresistive layers are disposed is provided with a predetermined potential.

Since a plurality of well layers on which piezoresistive layers are disposed can be insulated and isolated from one another by the first insulating layer and the junction planes between the well layers and the isolation layer to be reverse-biased, a predetermined potential can be set for each well layer. Therefore, by setting a predetermined potential for each well layer, a plurality of piezoresistive layers and the corresponding well layer can be reverse-biased with an appropriate voltage value. Consequently, the resistances of the plurality of piezoresistive layers can be appropriately controlled.

Preferably, the physical quantity sensor further includes a second insulating layer disposed on the surface of the first-conductivity-type well layer, and a first-conductivity-type shield layer is provided in the first-conductivity-type well layer located between the second insulating layer and the plurality of second-conductivity-type piezoresistive layers so as to overlie, in plan view, the plurality of second-conductivity-type piezoresistive layers.

When the surface of the second insulating layer is contaminated with soil, moisture, or the like, and the soil, moisture, or the like is electrically charged, an accumulation layer, depletion layer, or inversion layer may be formed in the piezoresistive layers, resulting in a change in resistance in some cases. However, when a shield layer is provided between the piezoresistive layers and the second insulating layer so as to overlie the piezoresistive layers, the shield layer intercepts the influence of electrical charges of the soil, moisture, or the like and suppresses formation of an accumulation layer, depletion layer, or inversion layer in the piezoresistive layers. Furthermore, the shield layer also intercepts electromagnetic noise entering from the outside. Accordingly, when a shield layer is provided so as to overlie the piezoresistive layers, changes in the resistance of the piezoresistive layers can be suppressed.

Preferably, the physical quantity sensor further includes a second insulating layer disposed on the surface of the first-conductivity-type well layer and a second-conductivity-type lead layer which is connected to the second-conductivity-type piezoresistive layers and disposed in the first-conductivity-type well layer, and the first-conductivity-type shield layer is provided in the first-conductivity-type well layer so as to be in contact with the second insulating layer and so as not to overlie, in plan view, the second-conductivity-type lead layer.

In such a configuration, the shield layer intercepts the influence of electrical charges of soil, moisture, or the like and prevents formation of an accumulation layer, depletion layer, or inversion layer in the well layer. Furthermore, the shield layer also intercepts electromagnetic noise entering from the outside. Consequently, since the potential in the well layer is appropriately controlled, dark currents flowing from the well layer to the piezoresistive layers can be appropriately controlled when the piezoresistive layers and the well layer are reverse-biased. Therefore, changes in the resistance of the piezoresistive layers can be suppressed.

Preferably, the first-conductivity-type shield layer has the same potential as that of the first-conductivity-type well layer. In such a configuration, the shield layer can stably intercept the influence of external charges, electromagnetic noise entering from the outside, or the like.

Preferably, the first-conductivity-type well layer is composed of one of two silicon substrates constituting a SOI substrate, the two silicon substrates being bonded together with an oxide film therebetween. In such a configuration, a physical quantity sensor according to the present invention can be realized.

### BRIEF DESCRIPTION OF THE DRAWINGS

FIG. 1 is a plan view of a physical quantity sensor according to a first embodiment of the present invention;

FIG. 2 is a cross-sectional view taken along the line II-II of FIG. 1 and viewed in the direction of the arrows;

FIG. 3 is an enlarged partial view of the area surrounded by the dotted-chain line III in FIG. 1;

FIG. 4 is a cross-sectional view taken along the line IV-IV of FIG. 3 and viewed in the direction of the arrows;

FIG. 5 is a schematic view of a bridge circuit according to the first embodiment;

FIGS. 6A to 6E are views illustrating a manufacturing process of a physical quantity sensor according to the first embodiment;

FIGS. 7A to 7D are views illustrating a manufacturing process of a physical quantity sensor according to the first embodiment;

FIG. 8 is a plan view of a physical quantity sensor according to a first modification example of the first embodiment;

FIG. 9 is a plan view of a physical quantity sensor according to a second modification example of the first embodiment;

FIG. 10 is a plan view of a physical quantity sensor according to a second embodiment;

FIG. 11 is a cross-sectional view taken along the line XI-XI of FIG. 10 and viewed in the direction of the arrows;

FIG. 12 is a cross-sectional view of a pressure sensor disclosed in Patent Document 1; and

FIG. 13 is a cross-sectional view of a diaphragm of the pressure sensor disclosed in Patent Document 1.

### DESCRIPTION OF THE PREFERRED EMBODIMENTS

Physical quantity sensors and manufacturing methods therefor according to the embodiments of the present invention will be described in detail below with reference to the drawings. Note that the dimensions are appropriately changed in the drawings.

### First Embodiment

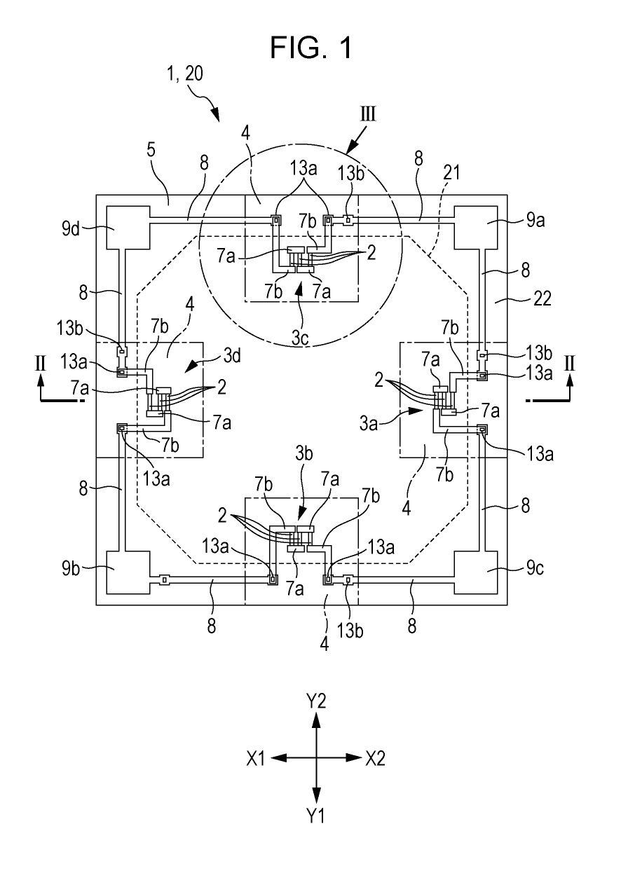

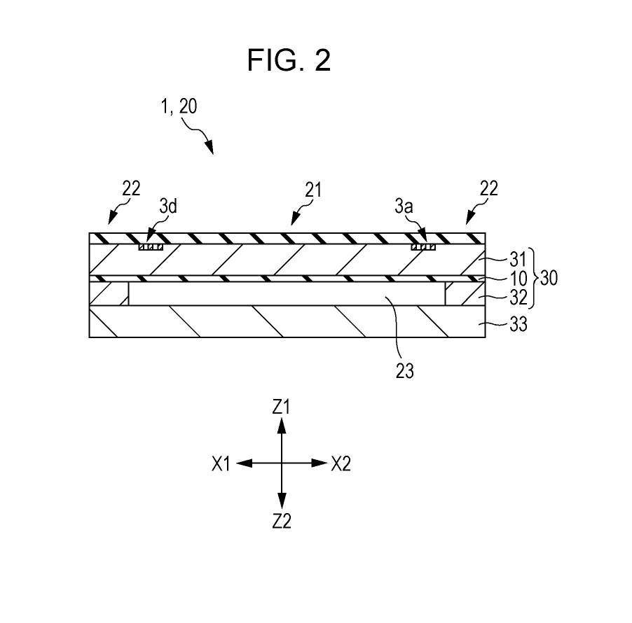

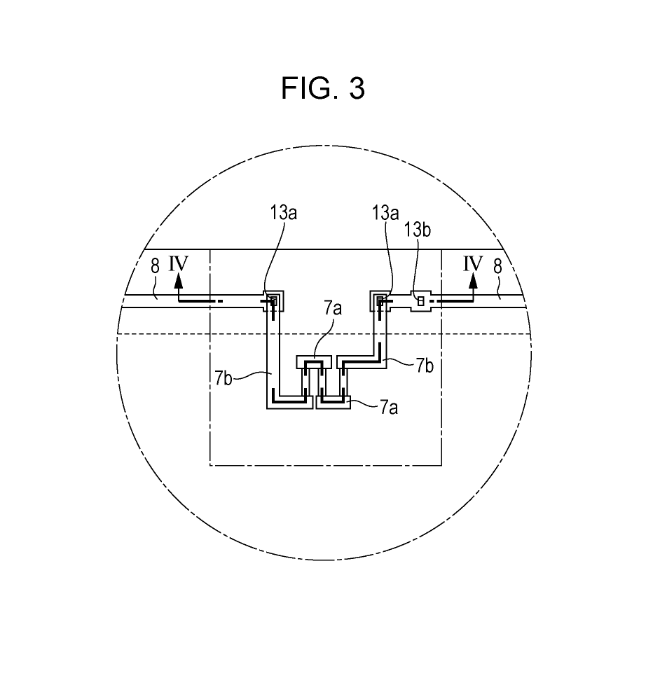

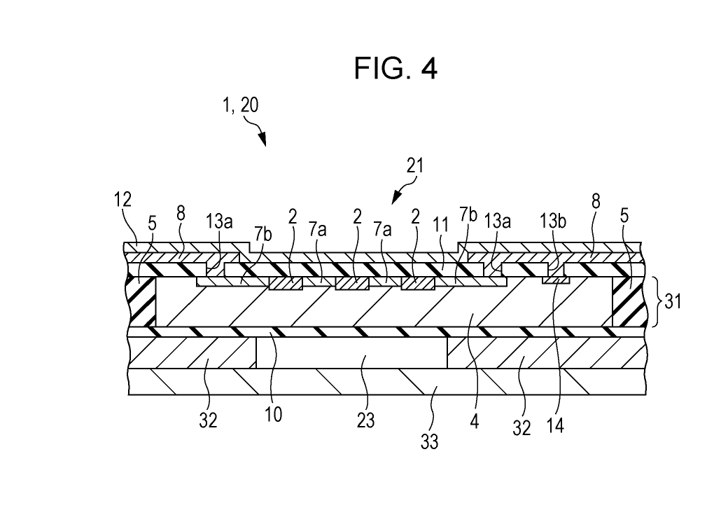

FIG. 1 is a plan view of a physical quantity sensor according to a first embodiment. FIG. 2 is a cross-sectional view taken along the line II-II of FIG. 1 and viewed in the direction of the arrows. FIG. 3 is an enlarged partial view of the area surrounded by the dotted-chain line III in FIG. 1. FIG. 4 is a cross-sectional view taken along the line IV-IV of FIG. 3 and viewed in the direction of the arrows.

A physical quantity sensor 1 according to this embodiment shown in FIG. 1 is a pressure sensor 20. The pressure sensor 20 is fabricated using a silicon-on-insulator (SOI) substrate. As shown in FIG. 2, a SOI substrate 30 has a structure in which a first silicon substrate 31 and a second silicon substrate 32 are bonded together with a first insulating layer 10 therebetween. The first insulating layer 10 according to this embodiment is composed of a silicon oxide film.

The physical quantity sensor 1 according to this embodiment is not limited to the pressure sensor 20, but may be a physical quantity sensor which detects a physical quantity, such as acceleration or load.

As shown in FIG. 2, the first silicon substrate 31 is located on the upper surface side (the Z1 direction), and the second silicon substrate 32 is located on the lower surface side (the Z2 direction). A cavity (recess) 23 is formed in the second silicon substrate 32, and the first insulating layer 10, the first silicon substrate 31, and the like on the cavity 23 constitute a diaphragm. In FIG. 1, the region of a diaphragm 21 is indicated by the dashed line. When a pressure is applied from a surface side of the first silicon substrate 31 (the Z1 direction shown in FIG. 2), the diaphragm 21 is deformed in response to the pressure, and the periphery of the diaphragm 21 is a fixed portion 22 in which deformation does not occur. The diaphragm 21 is deformed such that it is deflected toward the cavity 23.

As shown in FIG. 1, the diaphragm 21 according to this embodiment has a polygonal shape, in plan view, having four edges which are substantially parallel to the horizontal (X) direction or the front-back (Y) direction and located substantially in the center in the horizontal (X) direction or the front-back (Y) direction. A first piezoresistive element 3a, a second piezoresistive element 3b, a third piezoresistive element 3c, and a fourth piezoresistive element 3d are disposed substantially in the centers of the four edges.

Each of the piezoresistive elements 3a, 3b, 3c, and 3d according to this embodiment includes three piezoresistive layers 2 which are elongated in the front-back (Y) direction and arranged in parallel in the horizontal (X) direction at intervals, two connecting layers 7a which connect the three piezoresistive layers 2 in a meander shape, and lead layers 7b connected to both ends of the meander shape to connect the piezoresistive layers 2 to the outside.

As shown in FIG. 1, the piezoresistive elements 3a, 3b, 3c, and 3d are connected to pads 9a, 9b, 9c, and 9d through interconnection layers 8 connected to the lead layers 7b. The first piezoresistive element 3a and the second piezoresistive element 3b are connected in series through the interconnection layers 8 and a first output pad 9c. Furthermore, the third piezoresistive element 3c and the fourth piezoresistive element 3d are connected in series through the interconnection layers 8 and a second output pad 9d.

The first piezoresistive element 3a and the third piezoresistive element 3c are connected together through the interconnection layers 8 and a power source pad 9a, and the second piezoresistive element 3b and the fourth piezoresistive element 3d are connected together through the interconnection layers 8 and a ground pad 9b.

As shown in FIG. 1, all of the first output pad 9c, the second output pad 9d, the power source pad 9a, the ground pad 9b, and the interconnection layers 8 are disposed on the surface of the fixed portion 22.

The first output pad 9c, the second output pad 9d, the power source pad 9a, the ground pad 9b, and the interconnection layers 8 are formed by plating or sputtering using a good conductor, such as aluminum (Al) or gold (Au).

Hereinafter, the terms “P⁺-type impurity layer”, “P⁺⁺-type impurity layer”, “N⁺-type impurity layer”, and “N⁺⁺-type impurity layer” will be used. The terms “P⁺-type impurity layer” and “P⁺⁺-type impurity layer” each refer to a P-type semiconductor formed by doping a silicon substrate with, for example, boron (B) which is a trivalent element. The terms “N⁺-type impurity layer” and “N⁺⁺-type impurity layer” each refer to an N-type semiconductor formed by doping a silicon substrate with, for example, phosphorus (P) which is a pentavalent element. The “P⁺⁺-type impurity layer” and the “N⁺⁺-type impurity layer” have a larger amount of doping than the “P⁺-type impurity layer” and the “N⁺-type impurity layer”. In the “P⁺-type impurity layer” and the “N⁺-type impurity layer”, the amount of doping (impurity concentration) is about 10¹⁷ to 10¹⁸ cm⁻³. On the other hand, in the “P⁺⁺-type impurity layer” and the “N⁺⁺-type impurity layer”, the amount of doping (impurity concentration) is about 10¹⁹ to 10²⁰ cm⁻³. Therefore, the “P⁺⁺-type impurity layer” and the “N⁺⁺-type impurity layer” have a lower resistivity than the “P⁺-type impurity layer” and the “N⁺-type impurity layer”.

The piezoresistive layers 2 are formed as P⁺-type impurity layers on the surface side (in the Z1 direction) of the diaphragm 21 as shown in FIGS. 2 and 4. In each of the piezoresistive elements 3a, 3b, 3c, and 3d shown in FIG. 1, three P⁺-type impurity layers (piezoresistive layers 2), which are elongated in the front-back (Y) direction, are arranged in parallel in the horizontal (X) direction at intervals and are connected by two connecting layers 7a in a meander shape. That is, the longitudinal direction of each of the piezoresistive elements 3a, 3b, 3c, and 3d corresponds to the front-back (Y) direction.

The longitudinal direction of each of the piezoresistive elements 3a, 3b, 3c, and 3d is set such that, when the diaphragm 21 is deformed under an applied pressure, the resistances of the second piezoresistive element 3b and the third piezoresistive element 3c become large and the resistances of the first piezoresistive element 3a and the fourth piezoresistive element 3d become small.

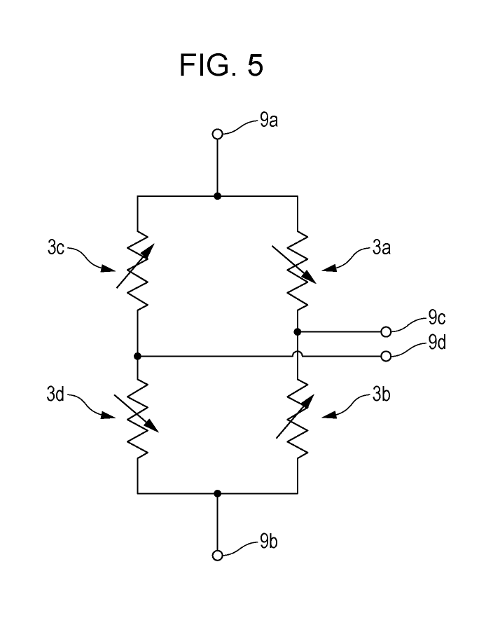

As shown in FIGS. 1 and 5, the four piezoresistive elements 3a, 3b, 3c, and 3d whose resistance changes in response to the deformation of the diaphragm 21 constitute a bridge circuit. The power source pad 9a, the first piezoresistive element 3a, the second piezoresistive element 3b, and the ground pad 9b are connected in series, and the power source pad 9a, the third piezoresistive element 3c, the fourth piezoresistive element 3d, and the ground pad 9b are connected in series. The first output pad 9c is connected between the first piezoresistive element 3a and the second piezoresistive element 3b, and the second output pad 9d is connected between the third piezoresistive element 3c and the fourth piezoresistive element 3d.

The bridge circuit according to this embodiment shown in FIGS. 1 and 5 is connected to a differential amplifier (not shown), a voltage is applied to the power source pad 9a, and the ground pad 9b is grounded. In the pressure sensor 20, when a pressure is applied from the surface side of the first silicon substrate 31 shown in FIG. 2, the diaphragm 21 is deflected, and the resistances of the piezoresistive layers 2 are changed in response to the deflection of the diaphragm 21. The potential of the first output pad 9c and the potential of the second output pad 9d, each of which is the midpoint potential of the bridge circuit, are changed, and the potential difference is amplified by the differential amplifier. Thus, the pressure is measured.

That is, when no pressure is applied to the diaphragm 21, the four piezoresistive elements 3a, 3b, 3c, and 3d are configured to have the same resistance. Accordingly, the potential of each of the first output pad 9c and the second output pad 9d is equal to half the voltage applied to the power source pad 9a, and the output from the differential amplifier is zero.

When a pressure is applied to the diaphragm 21, the resistance of each of the second piezoresistive element 3b and the third piezoresistive element 3c is increased, and the resistance of each of the first piezoresistive element 3a and the fourth piezoresistive element 3d is decreased. Accordingly, the potential of the first output pad 9c becomes larger than half the voltage applied to the power source pad 9a, and the potential of the second output pad 9d becomes smaller than half the voltage applied to the power source pad 9a. Consequently, the potential difference between the first output pad 9c and the second output pad 9d is amplified and outputted from the differential amplifier.

The piezoresistive layers 2 constituting each of the piezoresistive elements 3a, 3b, 3c, and 3d are disposed in the well layer 4, which is an N-type impurity layer, corresponding to the piezoresistive layers 2, as shown in FIGS. 1 and 4. The isolation layer 5, which is a P⁺-type impurity layer, is disposed between the well layers 4, and the well layers 4 are insulated and isolated from one another by the isolation layer 5.

As shown in FIG. 4, the connecting layers 7a connecting the piezoresistive layers 2 and the lead layers 7b connecting the piezoresistive layers 2 to the outside are disposed on the surface side of the first silicon substrate 31. The isolation layer 5 is disposed so as to pass through the first silicon substrate 31 from the surface of the first silicon substrate 31 to the surface of the first insulating layer 10. That is, the isolation layer 5 is an impurity layer having a conductivity type different from that of the first silicon substrate 31 and passes through the first silicon substrate 31 so that the well layers 4 can be insulated and isolated from one another.

A silicon substrate is, for example, formed by the Czochralski (CZ) method or the like, and is doped with an impurity element with a predetermined concentration. Thereby, a silicon substrate having little crystal defects can be obtained. The first silicon substrate 31 is a substrate composed of an N-type impurity crystal, for example, formed by the Czochralski (CZ) method or the like, and contains an N-type impurity layer. The piezoresistive layers 2, the connecting layers 7a, the lead layers 7b, and the isolation layer 5 are each formed by doping, i.e., singly doping, a corresponding impurity element into the N-type impurity layer having little crystal defects constituting the first silicon substrate 31. At this time, regions not doped with the impurity elements, in other words, regions in which the piezoresistive layers are surrounded by the isolation layer 5 as shown in FIG. 4, or regions in which the piezoresistive layers 2 are insulated and isolated from the other piezoresistive layers 2 by the end faces of the first silicon substrate 31 and the isolation layer 5 as shown in FIG. 1, are formed as the well layers, which are N-type impurity layers. In such a manner, according to this embodiment, since the N-type impurity layer of the silicon substrate 31 is used as the well layers 4, the piezoresistive layers 2, the connecting layers 7a, the lead layers 7b, and the isolation layer 5 can be each formed by singly doping an impurity element.

In this embodiment, the first silicon substrate 31 has an impurity concentration of about 10¹⁴ to 10¹⁵ cm⁻³ and a thickness of about 4.5 to 5.0 μm. The thickness of the first insulating layer 10 is about 0.3 μm. The junction depth of the piezoresistive layers 2 is about 1.5 to 2.0 μm. The junction depth of each of the connecting layers 7a and the lead layers 7b is about 0.8 to 1.0 μm.

A second insulating layer 11, for example, composed of phosphosilicate glass (PSG) or the like, is disposed on the surface of the first silicon substrate 31. First connection holes 13a and second connection holes 13b are formed in the second insulating layer 11. The interconnection layers 8 formed on the second insulating layer 11 are connected to the lead layers 7b through the first connection holes 13a and are connected to the well layer 4 through the second connection holes 13b.

A protective layer 12, for example, composed of a silicon nitride film formed by plasma chemical vapor deposition (CVD) or the like, is disposed on the interconnection layers 8. The protective layer 12 protects the pressure sensor 20 by suppressing mechanical damage and entry of moisture or the like.

In the pressure sensor 20 according to this embodiment, as shown in FIG. 4, the well layer 4 is insulated and separated using the isolation layer 5 which passes through the well layer 4 from the surface of the well layer 4 to the surface of the first insulating layer 10, and thus, no region is doubly doped with impurity elements in the N-type impurity layer of the first silicon substrate 31 in the periphery of the piezoresistive layers 2. Accordingly, it is possible to suppress occurrence of crystal defects in the piezoresistive layers 2 and in the periphery thereof. Consequently, in the pressure sensor according to this embodiment, leakage currents due to crystal defects can be suppressed.

Therefore, in accordance with this embodiment, it is possible to provide a pressure sensor which detects pressure using a piezoresistive effect and which has excellent detection accuracy.

In the first piezoresistive element 3a and the third piezoresistive element 3c according to this embodiment, as shown in FIGS. 1 and 4, currents flow from the power source pad 9a through the interconnection layers 8. At this time, for each of the piezoresistive elements 3a and 3c, the interconnection layer 8 is connected to the well layer 4 through the second connection hole 13b, and then is connected to the lead layer 7b through the first connection hole 13a. The potential at the position of the second connection hole 13b is equal to a potential obtained by subtracting the voltage drop between the power source pad 9a and the second connection hole 13b from the voltage of the power source pad 9a. Furthermore, for each of the piezoresistive elements 3a and 3c, the potential of the piezoresistive layers 2 is a potential obtained by subtracting the voltage drop through the second connection hole 13b, the interconnection layer 8, the lead layer 7b, and the meander line from the potential at the position of the second connection hole 13b. Since substantially no current flows into the well layer 4, substantially no voltage drop occurs, and the potential in the well layer 4 is fixed at the potential at the position of the second connection hole 13b.

In such a manner, in accordance with this embodiment, in each of the piezoresistive elements 3a and 3c, the piezoresistive layers 2 and the well layer 4 are reverse-biased by the voltage drop through the second connection hole 13b, the interconnection layer 8, the lead layer 7b, and the meander line, and the piezoresistive layers 2 are insulated and isolated from the well layer 4. Furthermore, the potential in the well layer 4 is fixed at a potential obtained by subtracting the voltage drop between the power source pad 9a and the second connection hole 13b from the voltage of the power source pad 9a.

In each of the piezoresistive elements 3b and 3d, insulation/isolation is provided in the same manner that in each of the piezoresistive elements 3a and 3c. However, the potential of the well layer 4 for each of the piezoresistive elements 3b and 3d is fixed at a potential obtained by subtracting the voltage drop between the first output pad 9c or the second output pad 9d and the second connection hole 13b from the potential of the first output pad 9c or the second output pad 9, i.e., the midpoint potential.

In this embodiment, components have the same shape and the same size for the piezoresistive elements 3a, 3c, 3b, and 3d. Accordingly, in the piezoresistive elements 3a, 3c, 3b, and 3d, since the piezoresistive layers 2 and the well layer 4 are reverse-biased at substantially the same voltage, dark currents are substantially the same. Therefore, the changes in resistance due to dark currents caused by reverse biasing are substantially the same for the piezoresistive elements 3a, 3c, 3b, and 3d.

Description will be made using the bridge circuit shown in FIG. 5. Assuming that the resistances of the piezoresistive elements 3a, 3c, 3b, and 3d are increased by the same amount by dark currents, in that case, since the potential of the first output pad 9c is decreased by the first piezoresistive element 3a and is increased by the second piezoresistive element 3b, offsetting results in no change in the potential. Furthermore, since the potential of the second output pad 9d is decreased by the third piezoresistive element 3c and is increased by the fourth piezoresistive element 3d, offsetting results in no change in the potential. The same applied to the case where the resistances of the piezoresistive elements 3a, 3c, 3b, and 3d are decreased by the same amount by dark currents.

Accordingly, when a bridge circuit is constituted by the piezoresistive elements 3a, 3c, 3b, and 3d according to this embodiment, since the changes in the midpoint potential for the same change in resistance are offset, it is possible to suppress degradation in detection accuracy due to dark currents caused by reverse biasing.

In this embodiment, the potential of the well layer 4 for each of the piezoresistive elements 3a and 3c is stably fixed at a potential obtained by subtracting the voltage drop between the power source pad 9a and the second connection hole 13b from the voltage of the power source pad 9a, and the potential of the well layer 4 for each of the piezoresistive elements 3b and 3d is stably fixed at a potential obtained by subtracting the voltage drop between the first output pad 9c or the second output pad 9d and the second connection hole 13b from the midpoint potential. In such a manner, in accordance with this embodiment, each of the well layers 4 on which the piezoresistive layers 2 are disposed is provided with a predetermined potential.

Therefore, in accordance with this embodiment, it is possible to provide a pressure sensor which detects pressure using a piezoresistive effect and which has excellent detection accuracy.

In accordance with this embodiment, a predetermined potential of each well layer 4 is set by the voltage drop between the power source pad 9a, the first output pad 9c, or the second output pad 9d and the second connection hole 13b. However, the configuration is not limited thereto. Each well layer 4 may be connected to a contact having a predetermined potential.

The piezoresistive elements 3a, 3b, 3c, and 3d according to this embodiment are, as shown in FIGS. 1 and 4, insulated and isolated by the first insulating layer 10 and the isolation layer 5 passing through the well layer 4, which is an N-type impurity layer, from the surface of the well layer 4 to the surface of the first insulating layer 10. In this embodiment, by using the first insulating layer 10 for insulating and isolating the piezoresistive elements 3a, 3b, 3c, and 3d from one another, junction planes between P⁺-type impurity layers and N-type impurity layers are reduced. Consequently, insulation/isolation of the piezoresistive elements 3a, 3b, 3c, and 3d according to this embodiment is satisfactory, and the pressure sensor 20 according to this embodiment has excellent detection accuracy for detecting pressure.

In contrast, in the pressure sensor 220 according to the related art example shown in FIG. 13, piezoresistive elements 203a and 203b are disposed in the P-type impurity layer 205 composed of the P-type semiconductor silicon substrate 231. In the piezoresistive elements 203a and 203b, piezoresistive layers 202a and 202b, which are P⁺-type impurity layers, are respectively disposed within the well layers 204a and 204b, which are N⁺-type impurity layers. When the well layers 204a and 204b and the P-type impurity layer 205 are reverse-biased, the piezoresistive elements 203a and 203b are insulated and isolated from one another. During reverse biasing, dark currents flow from the P-type impurity layer 205 into the well layers 204a and 204b through the junction planes between the P-type impurity layer 205 and the well layers 204a and 204b. Accordingly, in the pressure sensor 220 according to the related art example, since insulation/isolation is provided using only junction planes between reverse-biased well layers 204a and 204b and P-type impurity layer 205, i.e., semiconductor impurity layers, insulation/isolation between each of the well layers 204a and 204b and the P-type impurity layer 205 and between the well layers 204a and 204b is insufficient. Therefore, in the pressure sensor 220 according to the related art example, the piezoresistive elements 203a and 203b are unstable under the influence of potential variations of the P-type impurity layer 205 and the like.

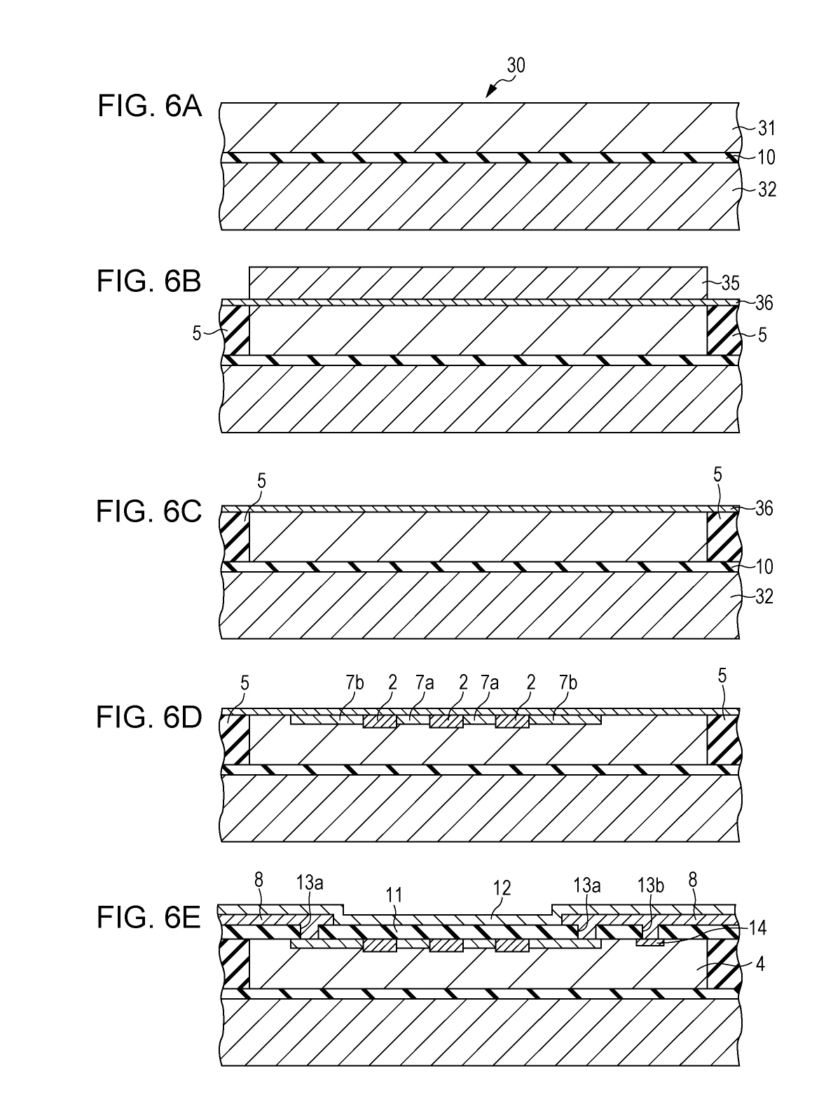

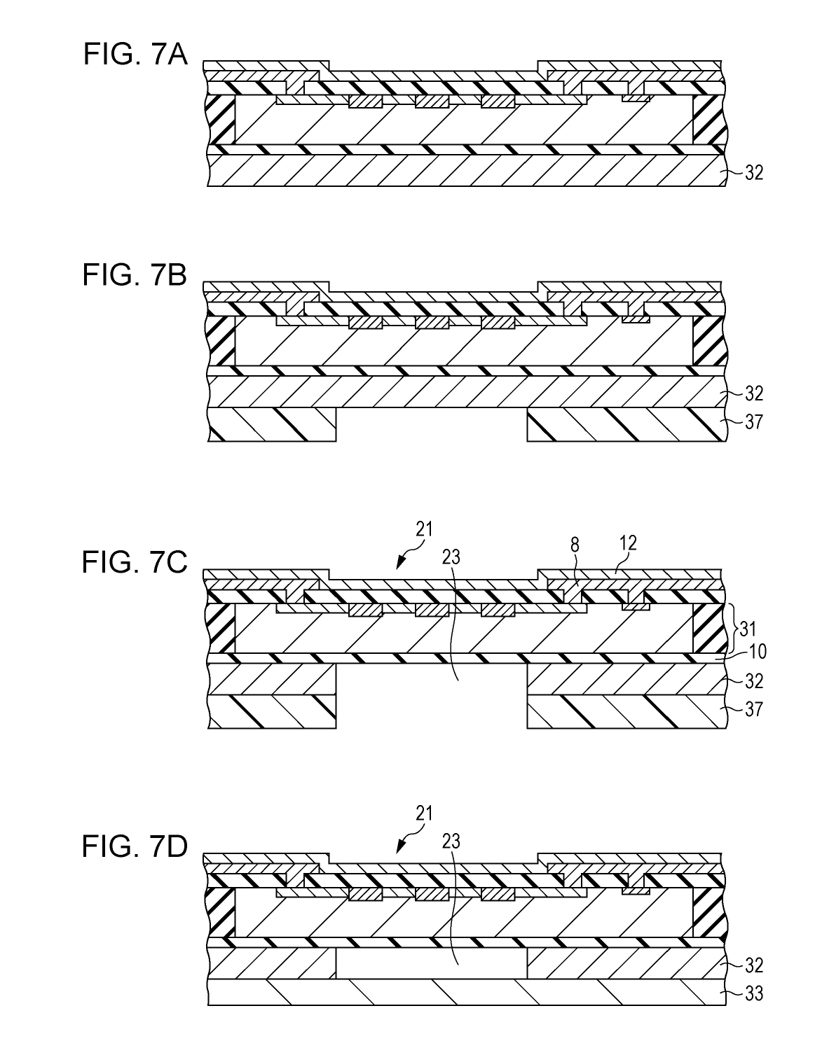

FIGS. 6A to 6E and 7A to 7D are views illustrating a manufacturing process of a physical quantity sensor according to the first embodiment. A manufacturing method of a pressure sensor according to this embodiment will be described with reference to FIGS. 6A to 6E and 7A to 7D. In the step shown in FIG. 6A, a SOI substrate 30 in which a first silicon substrate 31 and a second silicon substrate 32 are bonded together with a first insulating layer 10 therebetween is prepared.

In the step shown in FIG. 6B, the SOI substrate is subjected to thermal oxidation to form a thermally oxidized film 36 on the surface (upper surface) of the first silicon substrate 31. Next, a photoresist pattern 35 corresponding to an isolation layer 5 is formed by a photolithographic technique on the thermally oxidized film 36. Next, using the photoresist pattern 35 as a mask, a region in which the isolation layer 5 is to be formed is subjected to ion implantation with a P-type impurity element, such as boron (B). The isolation layer 5 is formed such that the P-type impurity element, such as boron (B), is diffused into the first silicon substrate 31 from the surface (upper surface) of the first silicon substrate 31 to the first insulating layer 10.

In the step shown in FIG. 6C, after the photoresist pattern 35 is entirely removed, annealing treatment is performed in order to activate the P-type impurity element, such as boron (B), and restore crystal defects or the like.

In the step shown in FIG. 6D, piezoresistive layers 2, connecting layers 7a, and lead layers 7b are formed by the same steps as those shown in FIGS. 6B and 6C.

In the step shown in FIG. 6E, a photoresist pattern corresponding to a contact layer 14 is formed by a photolithographic technique, and ion implantation is performed using an N-type purity element, such as phosphorus (P). Next, a second insulating layer 11, for example, composed of phosphosilicate glass (PSG) in which phosphorus (P) is added into a silicon oxide film, is formed on the surface (upper surface) of the first silicon substrate 31 by atmospheric pressure chemical vapor deposition (CVD) or the like. Next, a photoresist pattern corresponding to first connection holes 13a and second connection holes 13b are formed by a photolithographic technique. Next, using the photoresist pattern as a mask, the second insulating layer 11 and the thermally oxidized film 36 (not shown) are etched by reactive ion etching (RIE) or the like, and thereby the first connection holes 13a and the second connection holes 13b are formed. Next, in order to bring the interconnection layers 8 and the well layer 4 into ohmic contact with each other, annealing treatment is performed.

Next, a metal layer composed of aluminum (Al) or the like is formed by a film deposition technique, such as sputtering, on the second insulating layer 11. Using a photoresist pattern formed by a photolithographic technique as a mask, by etching the metal layer composed of aluminum (Al) or the like by RIE, the interconnection layers 8 are formed. Next, a protective layer 12 composed of a silicon nitride film or the like is formed by plasma CVD or the like on the interconnection layers 8.

In such a manner, the piezoresistive layers 2, the isolation layer 5, the interconnection layers 8, and the like are formed on the first silicon substrate 31, and thus the SOI substrate 30 is prepared.

In the step shown in FIG. 7A, in the SOI substrate 30 prepared in FIG. 6E, by grinding the surface of the second silicon substrate 32, which serves as a junction plane with a base substrate 33, the second silicon substrate 32 is formed into a predetermined thickness.

In the step shown in FIG. 7B, as an etching mask for forming a diaphragm, a photoresist pattern 37 is formed by a photolithographic technique on the surface (lower surface) of the second silicon substrate 32.

In the step shown in FIG. 7C, using the photoresist pattern 37 as a mask, the second silicon substrate 32 is etched by RIE or the like to form a diaphragm 21. For example, C₄F₈, SF₆, or the like can be used as the RIE gas. When etching of the second silicon substrate 32 proceeds and reaches the first insulating layer 10, the first insulating layer 10 serves as an etching stopper, and a cavity 23 having a polygonal shape, in plan view, is formed. In such a manner, the diaphragm 21 including the first insulating layer 10 which serves as an upper surface of the cavity 23, the first silicon substrate 31, the interconnection layers 8, the protective layer 12, and the like is formed.

In the step shown in FIG. 7D, the photoresist pattern 37 is removed entirely from the surface (lower surface) of the second silicon substrate 32. Then, a base substrate 33 is bonded to the surface (lower surface) of the second silicon substrate 32 in a vacuum state. Thereby, the cavity 23 between the diaphragm 21 and the base substrate 33 becomes a vacuum chamber, and an absolute pressure sensor structure is obtained.

As necessary, the surface (lower surface) of the base substrate 33 is ground to adjust the thickness thereof. Then, the substrate produced by bonding the SOI substrate 30 and the base substrate 33 is divided into chips by dicing. Each of the resulting chips serves as a pressure sensor 20.

### First Modification Example

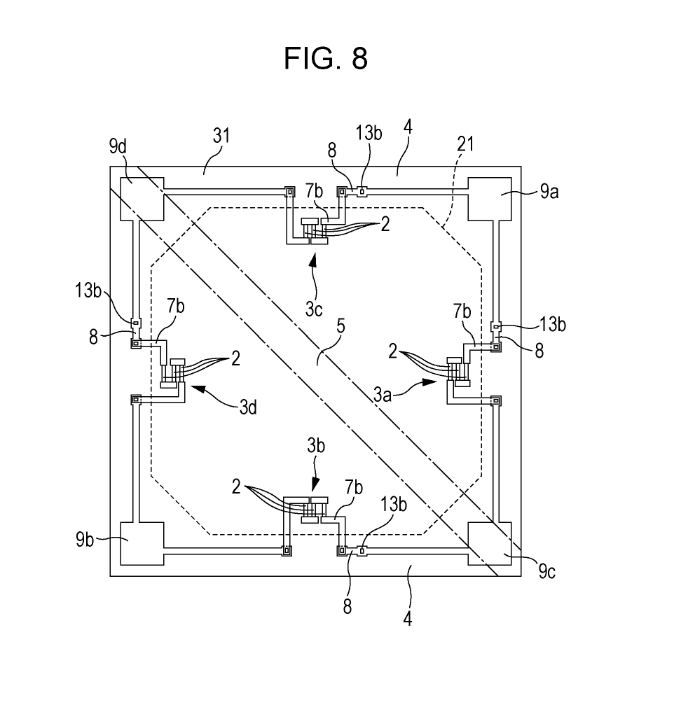

FIG. 8 is a plan view of a physical quantity sensor according to a first modification example of the first embodiment. An isolation layer 5 according to this modification example is formed so as to pass through the first silicon substrate 31 and extend in a direction connecting the first output pad 9c to the second output pad 9d as shown in FIG. 8. Accordingly, the isolation layer 5 is formed between the first piezoresistive element 3a and the third piezoresistive element 3c, which are located close to the power source pad 9a, and the second piezoresistive element 3b and the fourth piezoresistive element 3d, which are located far from the power source pad 9a. Insulation/isolation is provided by the isolation layer 5. The piezoresistive layers 2 provided in the first piezoresistive element 3a and the third piezoresistive element 3c are first piezoresistive layers because they are close to the power source pad 9a. The piezoresistive layers 2 provided in the second piezoresistive element 3b and the fourth piezoresistive element 3d are second piezoresistive layers because they are far from the power source pad 9a. In such a manner, the piezoresistive elements 3a, 3b, 3c, and 3d according to this modification example constitute a bridge circuit as shown in FIG. 8.

As shown in FIG. 8, the piezoresistive elements 3a and 3c located close to the power source pad 9a are disposed in the same well layer 4, and the piezoresistive elements 3b and 3d located far from the power source pad 9a are disposed in the same well layer 4. The potential of the well layer 4 in which the piezoresistive elements 3a and 3c are disposed is fixed at a potential obtained by subtracting the voltage drop between the power source pad 9a and the second connection hole 13b from the voltage of the power source pad 9a. Furthermore, the potential of the well layer 4 in which the piezoresistive elements 3b and 3d are disposed is fixed at a potential obtained by subtracting the voltage drop between the first output pad 9c or the second output pad 9d and the second connection hole 13b from the voltage of the first output pad 9c or the second output pad 9d.

In the piezoresistive elements 3a and 3c, the piezoresistive layers 2 and the well layer 4 are reverse-biased by the voltage drop from the second connection hole 13b through the interconnection layer 8, the lead layer 7b, and the meander line. In the piezoresistive elements 3b and 3d, reverse-biasing is performed in the same manner as that in the piezoresistive elements 3a and 3c.

Accordingly, in this modification example, since the piezoresistive elements 3a, 3b, 3c, and 3d are reverse-biased at substantially the same value as that of the well layer 4 whose potential is fixed, the changes in resistance due to dark currents in the piezoresistive elements 3a and 3c close to the adjustment circuit and in the piezoresistive elements 3b and 3d far from the adjustment circuit can be made to agree with each other, i.e., can be set to be substantially the same.

Therefore, in accordance with this modification example, it is possible to provide a pressure sensor which detects a physical quantity using a piezoresistive effect and which has excellent detection accuracy.

In this modification example, in a physical quantity sensor, four piezoresistive elements 3a, 3b, 3c, and 3d constitute a bridge circuit. However, the configuration is not limited thereto. It is also possible to constitute a half bridge circuit by connecting in series a power source pad 9a, a first piezoresistive element 3a, a first output pad 9c, a second piezoresistive element 3b, and a ground pad 9b. That is, the physical quantity sensor needs to include at least one piezoresistive element disposed at a position close to a power source pad 9a and one piezoresistive element disposed at a position far from the power source pad 9a.

### Second Modification Example

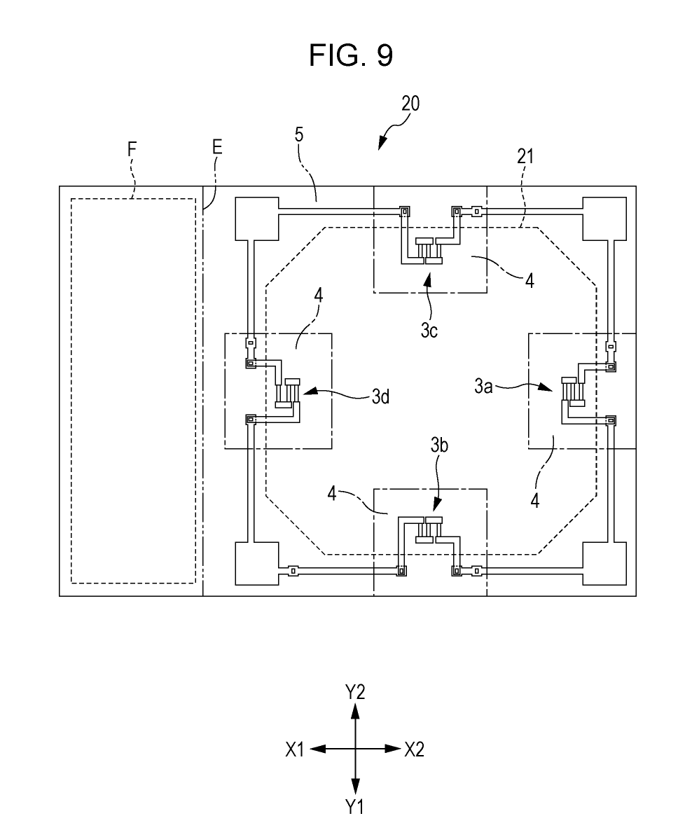

FIG. 9 is a plan view of a physical quantity sensor according to a second modification example of the first embodiment. An isolation layer 5 according to this modification example is provided in a region located in the right side of the double-dotted chain line E shown in FIG. 9 and outside four well layers 4. Furthermore, a device, such as an IC, is provided in a region surrounded by the dashed line F shown in FIG. 9.

In this modification example, as shown in FIG. 9, the isolation layer 5 is provided so as to surround the periphery of the well layer 4 in which a fourth piezoresistive element 3d is disposed. Therefore, as shown in FIG. 9, the fourth piezoresistive element 3d can be disposed in the central region, while other piezoresistive elements 3a, 3b, and 3c are disposed in peripheral regions. That is, even if the fourth piezoresistive element 3d is disposed in the central region, the fourth piezoresistive element 3d can be insulated and isolated from the other piezoresistive elements 3a, 3b, and 3c and the device, such as an IC, provided in the region surrounded by the dashed line F.

The fourth piezoresistive element 3d disposed in the well layer 4 surrounded by the isolation layer 5 can be insulated and isolated without being restricted by the layout. Consequently, it is possible to secure a space for providing a device, such as an IC, on the left side (X1 direction side) of the fourth piezoresistive element 3d as shown in FIG. 9. Since a device, such as an IC, and the pressure sensor 20 can be disposed on the same silicon substrate or the like, a large reduction in cost and size can be achieved.

In this modification example, the isolation layer 5 is provided so as to surround the well layer 4 in which the fourth piezoresistive element 3d is disposed. However, the configuration is not limited thereto. The isolation layer 5 may be provided so as to surround the well layer 4 in which any of the other piezoresistive elements 3a, 3b, and 3c is disposed.

### Second Embodiment

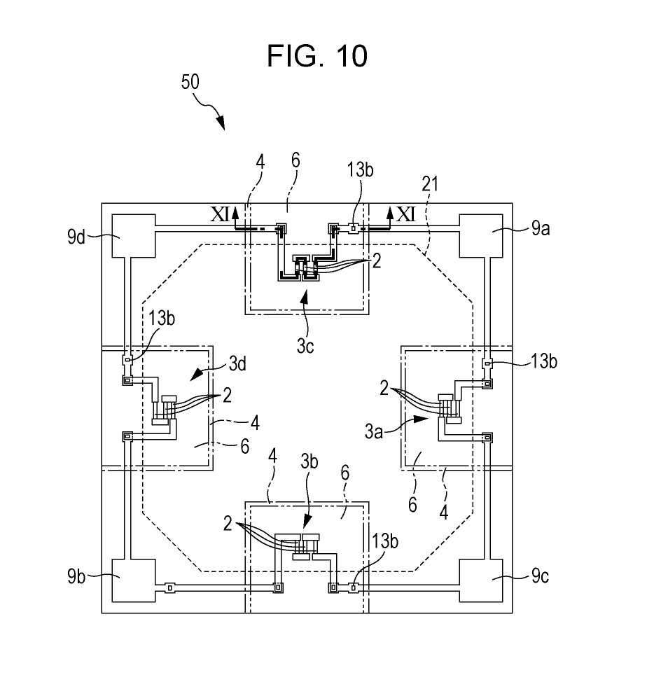

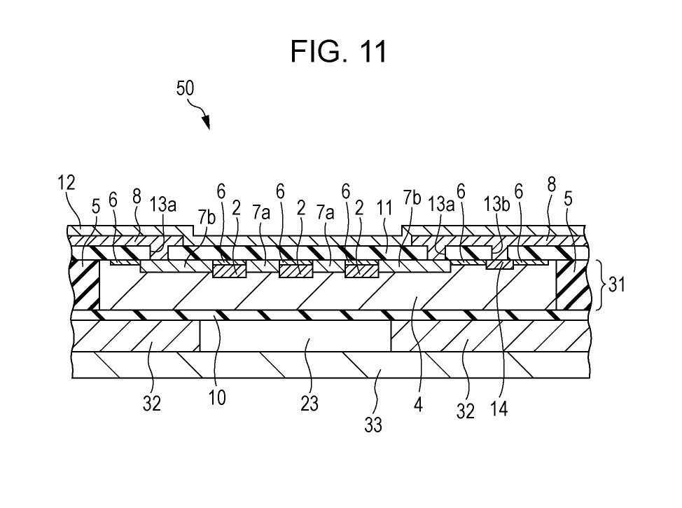

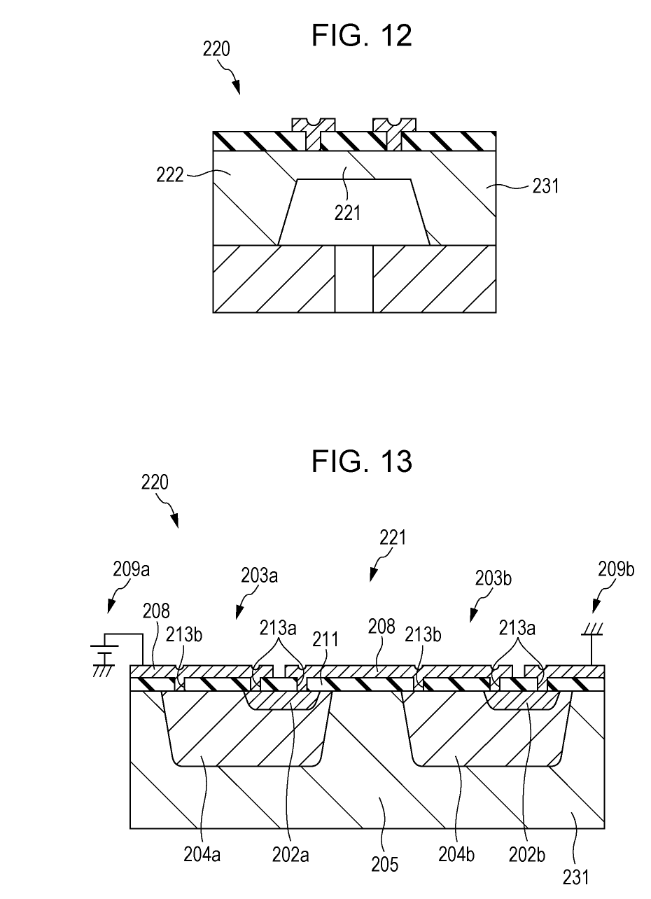

FIG. 10 is a plan view of a physical quantity sensor according to a second embodiment. FIG. 11 is a cross-sectional view taken along the line XI-XI of FIG. 10 and viewed in the direction of the arrows. In the second embodiment, the same components as those in the first embodiment are designated by the same reference numerals as those in the first embodiment.

The physical quantity sensor according to this embodiment is a pressure sensor as in the first embodiment. As shown in FIGS. 10 and 11, a pressure sensor 50 according to this embodiment differs from the pressure sensor 20 according to the first embodiment shown in FIG. 4 in that shield layers 6 are provided.

As shown in FIGS. 10 and 11, a shield layer 6 is provided for each of the piezoresistive elements 3a, 3b, 3c, and 3d, and is disposed so as to overlie, in plan view, the piezoresistive layers 2 in each well layer 4. The shield layer 6 has a region which is in contact with and overlies, in plan view, the well layer 4, and is connected to the well layer 4. Therefore, the shield layer 6 has the same potential as that of the well layer 4.

The shield layer 6 is an N⁺⁺-type impurity layer doped with an impurity element, such as phosphorus (P). As shown in FIG. 11, the shield layer 6 is provided between the piezoresistive layers 2 and the second insulating layer 11 and between the well layer 4 and the second insulating layer 11.

It is known that when an insulating layer is disposed on a P⁺-type impurity layer or N⁺-type impurity layer, the surface of the insulating layer is contaminated with soil, moisture, or the like, and the soil, moisture, or the like is electrically charged, the resistance of the P⁺-type impurity layer or N⁺-type impurity layer is changed. That is, an accumulation layer, depletion layer, or inversion layer is formed in the P⁺-type impurity layer or N⁺-type impurity layer in response to the amount of charge on the insulating layer, resulting in a change in resistance.

Furthermore, in a pressure sensor including piezoresistive layers disposed in a well layer, when the resistance of the well layer is changed, the potential distribution in the well layer changes. As a result, the reverse biasing voltage for the piezoresistive layers and the well layer may change, and a dark current which is the reverse bias current may change, resulting in a change in the resistance of the piezoresistive layers in some cases. Furthermore, when an inversion layer occurs in the well layer, a leakage current may flow in the inversion layer, resulting in a change in the resistance of the piezoresistive layers in some cases.

In this embodiment, the shield layer 6, which is the N⁺⁺-type impurity layer, is provided between the piezoresistive layers 2 and the second insulating layer 11 and between the well layer 4 and the second insulating layer 11. Therefore, even when the surface of the second insulating layer 11 is contaminated with electrically charged soil, moisture, or the like, the shield layer 6, which is the N⁺⁺-type impurity layer, intercepts the influence thereof and suppresses formation of an accumulation layer, depletion layer, or inversion layer in the piezoresistive layers 2 and the well layer 4, and thus the change in the resistance of the piezoresistive layers 2 is suppressed. Furthermore, the shield layer 6 also intercepts electromagnetic noise entering from the outside. Therefore, changes in the resistance of the piezoresistive layers due to electromagnetic noise entering from the outside can be suppressed. In such a manner, in accordance with this embodiment, charges of soil or the like, and disturbance, such as electromagnetic noise entering from the outside, are intercepted by the shield layer 6.

Therefore, in accordance with this embodiment, it is possible to provide a pressure sensor which detects pressure using a piezoresistive effect and which has excellent detection accuracy.

The potential of the well layer 4 according to this embodiment is fixed at a predetermined potential as in the first embodiment. The shield layer 6 is connected to the well layer 4. Consequently, since the potential of the shield layer 6 according to this embodiment is fixed at a predetermined potential, disturbance from the outside can be stably intercepted.

By decreasing the impurity concentration of the piezoresistive layers 2, the sensitivity of the pressure sensor 50 can be increased. When the impurity concentration of the piezoresistive layers 2 is decreased, the resistance of the piezoresistive layers 2 becomes sensitive to charges on the second insulating layer 11 and is likely to be changed. Therefore, the shield layer 6 is an important component in increasing the sensitivity of the pressure sensor 50.

In accordance with this embodiment, as shown in FIG. 11, the upper surface and lower surface of each piezoresistive layer 2 are insulated and isolated by reverse biasing from the shield layer 6 at the top and the well layer 4 at the bottom, and leakage currents from the upper surface and lower surface of the piezoresistive layer 2 is suppressed.

Surfaces of a silicon substrate are exposed to the atmosphere in the manufacturing process, and therefore are likely to be contaminated. Furthermore, an interface between a silicon (Si) substrate and a silicon oxide (SiO₂) film is a junction plane between heterogeneous substances, i.e., Si and SiO₂, and presence of an interface state at the interface is known. Furthermore, it is also known that charges are accumulated in a silicon oxide film. Consequently, when a current flows in the Si surface or along the Si/SiO₂ interface, it may be increased or decreased under the influence of soil on the Si surface, the interface state, or charges in SiO₂. For example, when carriers are trapped in the interface state or detrapped from the interface state, a leakage current occurs at the Si/SiO₂ interface between the silicon (Si) substrate and the silicon dioxide (SiO₂) film.

As shown in FIG. 11, the shield layer 6 according to this embodiment is provided between each of the piezoresistive layers 2 and the second insulating layer 11. Consequently, according to this embodiment, since the piezoresistive layers 2 are formed in the homogeneous, clean silicon crystal, currents flowing in the piezoresistive layers 2 are stable. In such a manner, the shield layer 6 according to this embodiment has a function of providing the piezoresistive layers 2 in the homogeneous, clean silicon crystal, in addition to the function of intercepting disturbance.

Therefore, in accordance with this embodiment, it is possible to provide a pressure sensor which detects pressure using a piezoresistive effect and which has excellent detection accuracy.

In this embodiment, the shield layer 6 is provided between each of the piezoresistive layers 2 and the second insulating layer 11 and between the well layer 4 and the second insulating layer 11. However, the configuration is not limited thereto. The shield layer 6 may be provided either between each of the piezoresistive layers 2 and the second insulating layer 11 or between the well layer 4 and the second insulating layer 11.

What is claimed is:

1. A physical quantity sensor which detects a physical quantity using a piezoresistive effect, comprising:
a first-conductivity-type well layer disposed on a first insulating layer;
a plurality of second-conductivity-type piezoresistive layers disposed on a surface side of the first-conductivity-type well layer; and
a second-conductivity-type isolation layer disposed between the plurality of second-conductivity-type piezoresistive layers so as to pass through the first-conductivity-type well layer from a surface of the first-conductivity-type well layer to a surface of the first insulating layer.

2. The physical quantity sensor according to claim 1, wherein the plurality of second-conductivity-type piezoresistive layers include a first piezoresistive layer disposed at a position close to a power source pad and a second piezoresistive layer disposed at a position far from the power source pad;
a bridge circuit is constituted by a first piezoresistive element including the first piezoresistive layer and a second piezoresistive element including the second piezoresistive layer; and
the isolation layer is disposed between the first piezoresistive element and the second piezoresistive element.

3. The physical quantity sensor according to claim 1, wherein the second-conductivity-type isolation layer is disposed so as to surround the first-conductivity-type well layer.

4. The physical quantity sensor according to claim 1, wherein each of first-conductivity-type well layers on which the plurality of second-conductivity-type piezoresistive layers are disposed is provided with a predetermined potential.

5. The physical quantity sensor according to claim 1, further comprising a second insulating layer disposed on the surface of the first-conductivity-type well layer,
wherein a first-conductivity-type shield layer is provided in the first-conductivity-type well layer located between the second insulating layer and the plurality of second-conductivity-type piezoresistive layers so as to overlie, in plan view, the plurality of second-conductivity-type piezoresistive layers.

6. The physical quantity sensor according to claim 1, further comprising a second insulating layer disposed on the surface of the first-conductivity-type well layer, and a second-conductivity-type lead layer which is connected to the second-conductivity-type piezoresistive layers and disposed in the first-conductivity-type well layer,
wherein a first-conductivity-type shield layer is provided in the first-conductivity-type well layer so as to be in contact with the second insulating layer and so as not to overlie, in plan view, the second-conductivity-type lead layer.

7. The physical quantity sensor according to claim 5, wherein the first-conductivity-type shield layer has the same potential as that of the first-conductivity-type well layer.

8. The physical quantity sensor according to claim 6, wherein the first-conductivity-type shield layer has the same potential as that of the first-conductivity-type well layer.

9. The physical quantity sensor according to claim 1, wherein the first-conductivity-type well layer is composed of one of two silicon substrates constituting a SOI substrate, the two silicon substrates being bonded together with an oxide film therebetween.
